(19) United States
(12) Patent Application Publication
(10) Pub. No.: US 2026/0094661 A1
(43) Pub. Date: Apr. 2, 2026

(54) METHOD AND SYSTEM FOR STORING SPD DATA FOR ENHANCING POST PACKAGE REPAIR

(71) Applicant: Quanta Computer Inc., Taoyuan City (TW)

(72) Inventors: Yu-Ting Lin, Taoyuan City (TW); Mao-Wen Chen, Taoyuan City (TW); Wei-De Li, Taoyuan City (TW); Cing-Hao Yang, Taoyuan City (TW)

(21) Appl. No.: 18/903,903

(22) Filed: Oct. 1, 2024

(51) Int. Cl. G11C 29/44; G11C 29/42; G11C 29/46

(52) U.S. Cl. CPC G11C 29/44; G11C 29/42; G11C 29/46

(57) ABSTRACT

A method and system for storing data relating to post package repairs for memory rows in a memory module. An error in a row of a memory bank of the memory module is determined. A software post package repair is performed on the row on an initial boot of the computer system. A number of software post package repairs performed on the row is incremented and stored in a permanent storage device such as an EEPROM of the memory module. The stored software post package repair count may be used to determine whether to perform a software post package repair on the row or whether to perform a hardware post package repair on the row on a subsequent boot of the computer system.

### TECHNICAL FIELD

The present invention relates generally to repairing memory modules, and more specifically, to storing repair data in SPD for the memory module for enhancing post package repair of the memory module.

### BACKGROUND

Servers are employed in large numbers for high demand applications, such as network based systems or data centers. The emergence of cloud computing applications has increased the demand for data centers. Data centers have numerous servers that store data and run applications accessed by remotely connected, computer device users. A typical data center has physical rack structures with attendant power and communication connections. Each rack may hold multiple application servers and storage servers. Each server generally includes hardware components such as processors, memory devices, network interface cards, power supplies, and other specialized hardware. Each of the servers generally includes a baseboard management controller that manages the operation of the server and communicates operational data to a central management station that manages the servers of the rack.

A typical server has a processing unit that may have multiple cores for computing operations that all rely on functional Dynamic Random-Access Memory (DRAM) memory in the form of dual in line memory modules (DIMMs). A DIMM typically includes a circuit board with an edge connector and a series of memory chips that are each organized in banks of memory blocks. Identifying defective memory blocks in DIMMs and repairing the defect, if possible after installation of the DIMM is desirable as memory is crucial to the operation of central processing units on the server.

Post Package Repair (PPR) is a process to remedy defects in DRAM DIMMs after installation of the DIMMs in a computer system. For DRAM DIMMs that support the PPR process, the Basic Input/Output System (BIOS) of the computer system can detect a single row failure in each DIMM bank and execute the PPR to replace the defective row with a spare row of DIMMs. The two most common PPR types are soft PPR (sPPR) and hard PPR (hPPR). Soft PPR is a non-destructive repair method used to temporarily fix faulty rows in the DRAM DIMM. The soft PPR process remaps the defective row to a spare row in the DIMM through reconfiguration of software. This process is a quicker and more efficient way to repair the defect rather than a physical rerouting to the spare row in the DIMM. In contrast, hPPR is a hardware-level change process that permanently replaces the faulty DIMM rows by providing a physical reroute of signals for the faulty row to the spare row. The hPPR type of repair is more robust and provides a long-term fix for memory errors. However, performing the hPPR is more time consuming and thus preferably only used when irrecoverable errors occur in the memory modules or errors during manufacturing the memory modules.

The present PPR process is outlined in FIG. 1. The BIOS system determines when a number of DIMM errors in a memory bank has occurred that exceeds a threshold value (10). When the number of detected DIMM errors in a bank reach a threshold number of errors, a PPR is triggered during a subsequent boot of the system for each defective row in the memory bank (12). The routine determines whether the PPR is enabled and the PPR type setting in the BIOS setup (14). Thus, if the PPR type is sPPR, the routine will execute the sPPR (16) for a defective row and find a spare row of memory in a DIMM to remap the defective row to the spare row. The system will then continue to boot (18). If the PPR type is hPPR (14), the routine will execute a hPPR (20) to physically reroute connections to a spare row to replace the defective row of memory. The system will then continue to boot (18). If the PPR is disabled (14), the routine will continue the boot process (18).

There are some disadvantages to the current PPR routine. First, information about known memory defects is primarily stored in non-volatile random-access memory (NVRAM) to allow for preparatory PPR, which helps prevent run-time errors by repairing errors in memory rows prior to boot up. However, such information stored on NVRAM is vulnerable to various conditions such as BIOS updates, hardware replacements, clearing Complementary Metal-Oxide-Semiconductor (CMOS) components, etc. These scenarios can lead to the clearing of data in NVRAM and loss of DIMM error information that prevent effective preparatory PPR. Second, the type of PPR can only be selected in the BIOS setup, and a single type of PPR is applied to all DIMM error repairs during a single power on self test (POST) routine. This lacks flexibility of using either the sPPR or hPPR for different DIMMs with different fault frequencies. Third, the hPPR is not efficiently used as some memory rows in a DIMM may be relatively fragile and exhibit high failure rates due to hardware defects, frequent access, or other reasons. Executing only the sPPR during every boot for such errors based on the BIOS setting is inefficient and time consuming for repair of these errors as the sPPR is performed for each boot as opposed to eliminating the sPPR process after the hPPR is performed.

Thus, there is a need for a routine that allows efficient utilization of PPR by preserving information about known memory defects. There is also a need for storing PPR related data useful for repairs on a memory module that may be used for any system using the memory module. There is also a need for efficient application of either a sPPR or a hPPR depending on fault data for a memory module.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a method of repairing a memory module in a computer system is disclosed. An error in a row of a memory bank of the memory module is determined. A software post package repair is performed on the row on an initial boot of the computer system. A number of software post package repairs performed on the row stored in a permanent storage device of the memory module is incremented. On a subsequent boot of the computer system, a determination whether to perform a software post package repair on the row is made based on the stored number of software post package repairs.

A further implementation of the example method is where the permanent storage device is an Electrically Erasable Programmable Read-Only Memory (EEPROM). Another implementation is where the example method includes determining whether to perform a hardware post package repair for the row based on the stored number of software post package repairs. Another implementation is where the example method includes performing the hardware post package repair on the row. The determination is made based on whether the stored number of software post package repairs exceed a threshold value. The stored number of software post package repairs is erased from the permanent storage device after performing the hardware post package repair on the row. Another implementation is where the example method includes storing a timestamp of the failure and a location of the row in the memory block in a programmable block of the permanent storage device. The stored number of software post package repairs is stored in the programmable block of the permanent storage device. Another implementation is where the programmable block is a serial presence detect data region. Another implementation is where the memory module is a dual in line memory module, and the memory bank is one of a plurality of memory banks on the module. Another implementation is where a basic input output system performs the software post package repair on the row. The basic input output system includes a memory test routine, and the memory test routine determines the error in the row. Another implementation is where the example method includes determining whether to execute the memory test routine based on the stored number of software post package repairs. Another implementation is where the row is one of a plurality of rows in the memory bank and a number of software post package repairs is stored in the permanent storage device for each row of the plurality of rows with a determined error. The example method further includes determining there is no storage for a new number of software post package repairs for the row. An error frequency for each row of the plurality of rows with a determined error is determined. The error frequency is determined based on the stored number of software post package repairs. A hardware post package repair on the row with the highest error frequency. The stored number of software post package repairs for the row with the highest error frequency is erased from the permanent storage device. The new number of software post package repairs is stored in place of the erased stored number.

According to certain aspects of the present disclosure, a computer system is disclosed. The computer system includes a memory module having a memory bank and a permanent storage device. A processor executes a basic input output system. The basic operating system causes the processor to perform operations, including determining an error in a row of a memory bank of the memory module on an initial boot of the computer system. The operations include performing a software post package repair on the row. The operations include incrementing a number of software post package repairs performed on the row stored in the permanent storage device. The operations include determining whether to perform a software post package repair on the row based on the stored number of software post package repairs on a subsequent boot of the computer system.

A further implementation of the example computer system is where the permanent storage device is an Electrically Erasable Programmable Read-Only Memory (EEPROM). Another implementation is where the operations further include determining whether to perform a hardware post package repair for the row based on the stored number of software post package repairs. Another implementation is where the operations further include performing the hardware post package repair on the row. The determination is made based on whether the stored number of software post package repairs exceed a threshold value. The operations further include erasing the stored number of software post package repairs from the permanent storage device after performing the hardware post package repair on the row. Another implementation is where the operations further include storing a timestamp of the failure and a location of the row in the memory bank in a programmable block of the permanent storage device. The stored number of software post package repairs is stored in the programmable block of the permanent storage device. Another implementation is where the programmable block is a serial presence detect data region. Another implementation is where the memory module is a dual in-line memory module, and the memory bank is one of a plurality of memory banks on the module. Another implementation is where the basic input output system includes a memory test routine. The memory test routine determines the error in the row. Another implementation is where the operations further include executing the memory test routine based on the stored number of software post package repairs.

According to certain aspects of the present disclosure, a computer-program product tangibly embodied in a non-transitory machine-readable storage medium is disclosed. The computer-program product includes instructions configured to cause a data processing apparatus to perform operations including determining an error in a row of a memory bank of the memory module. The operations include performing a software post package repair on the row on an initial boot of the computer system. The operations include incrementing a number of software post package repairs performed on the row stored in a permanent storage device of the memory module. The operations include determining whether to perform a software post package repair on the row based on the stored number of software post package repairs on a subsequent boot of the computer system.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a flow diagram of a prior art PPR routine for DIMMs;

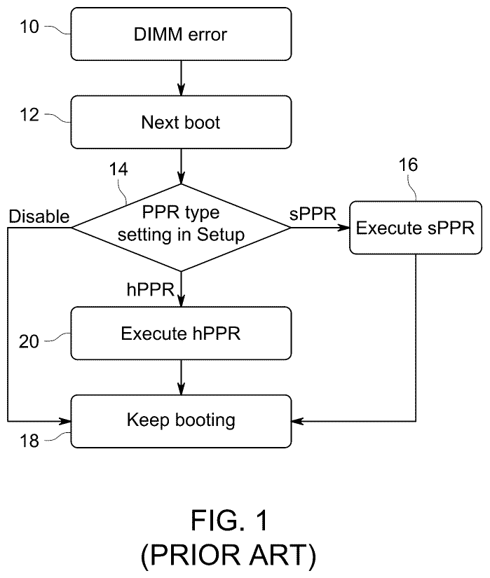

FIG. 2 is a block diagram of a computer system that includes DIMMs requiring PPR for the example repair procedure for storing PPR data on the DIMMs, according to certain aspects of the present disclosure;

FIG. 3 shows an example memory module of the computer system in FIG. 2, according to certain aspects of the present disclosure;

FIG. 4 is a table of the blocks of serial presence detect data in a memory module used by the example repair procedure to store PPR data, according to certain aspects of the present disclosure;

FIG. 5 is a flow diagram of an example repair routine that uses access of stored PPR data on a DIMM to determine a type of PPR for addressing DIMM errors, according to certain aspects of the present disclosure; and

FIG. 6 is a flow diagram of another example repair routine that uses access of stored PPR data on the DIMM to determine application of PPR, according to certain aspects of the present disclosure.

### DETAILED DESCRIPTION

The disclosure is directed to an example method to repair a memory module in a computer system. The method is based on saving information about failed rows in memory modules, such as DIMMs in the Serial Presence Detect (SPD) block storage on the DIMM for utilization in executing a Post Package Repair (PPR). Thus, the number of software post package repairs performed on each row of each memory bank of the memory is stored in a permanent storage device of the memory module An SPD chip on a DIMM is a permanent storage device that is an Electrically Erasable Programmable Read-Only Memory (EEPROM) chip holding 1024 Hex bytes of information about the DIMM. This identifies the module to the BIOS during the power-on self test (POST) procedure so the system has fault information about memory blocks on the DIMM to effectively execute types of PPR. Since the SPD data is stored in the EEPROM on a DIMM, the SPD data can be accessed on subsequent boots without relying on NVRAM. This prevents data loss on memory errors due to NVRAM clearing and provides historical error records for the PPR process on the DIMM. By recording the failed rows of memory blocks in the DIMM and their sPPR history in the SPD data in the EEPROM, the example method allows the BIOS setup to perform preparatory PPR for a DIMM without relying on NVRAM data during each boot, even after memory or hardware replacements. Additionally, the example method can automatically change the type of PPR performed during the POST routine. For memory rows with higher failure rates, the system can perform a desired type of PPR (either soft or hard) when the failure rate meets a user-defined threshold of a sPPR count.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

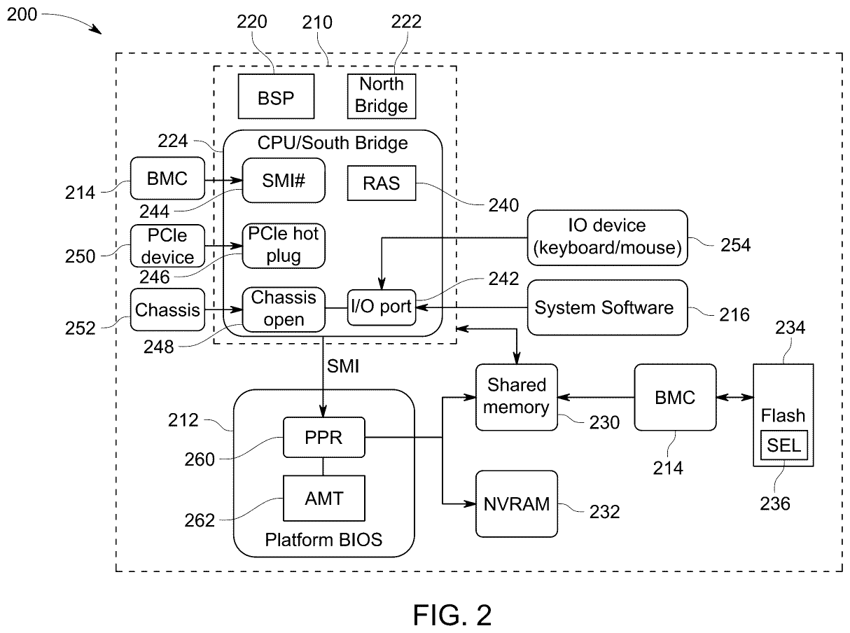

FIG. 2 is a block diagram of a computer system 200 that includes functionality for efficient and flexible deployment of Post Package Repair (PPR) of memory modules based on permanently stored Serial Presence Detect (SPD) data. In this example, the computer system 200 is a server, but the principles disclosed herein may be incorporated in any computer system having an operating system and memory modules that require repair for errors after installation. The computer system 200 includes a central processing unit (CPU) 210, a platform BIOS 212, a baseboard management controller (BMC) 214, and an operating system (OS) 216. The CPU 210 in this example is a chip set that may include a set of processing cores, including a bootstrap processor (BSP) 220 as well as a north bridge chip 222, and a south bridge chip 224.

In this example, the north bridge chip 222 handles memory operations. The south bridge chip 224 performs basic input/output functions for the computer system 200. Another function of both the north bridge and south bridge chips 222 and 224 is to handle different reliability-availability-serviceable (RAS) features. The RAS features are designed to increase reliability and availability, and facilitate service of peripheral components in the computer system 200. In this example, RAS features detect device errors in peripheral components such as add-on cards, dual in line memory modules (DIMM) s, and hard disk drives (HDD) s.

The computer system 200 includes a shared volatile memory 230 that may be static random access memory (SRAM) or dynamic random access memory (DRAM) in the form of multiple DIMMs that may be inserted in sockets on the motherboard in proximity to the CPU 210. The computer system 200 also includes a non-volatile memory 232, which may be a flash memory or a similar device. A dedicated BMC non-volatile flash memory 234 stores BMC firmware, as well as a system error log (SEL) 236. In this example, the non-volatile memory 232 may be the same flash memory as the dedicated BMC non-volatile flash memory 234. There may also be separate flash memories for the BMC 214 and the CPU 210. The BMC 214 can access the dedicated BMC non-volatile flash memory 234 to add entries in the SEL 236. An external device such as a management server in a datacenter may communicate via a network interface to the BMC 214 to read entries in the SEL 236. Alternatively, during production process, test equipment may access the BMC 214 to read test data that may be stored in the SEL 236. The BMC 214 can also access data written into the shared volatile memory 230.

In this example, the computer system 200 includes various hardware peripheral devices that access the input/output functions managed by the south bridge chip 224. The hardware peripheral devices in this example include peripheral component interface express (PCIe) devices, dual in line memory modules (DIMM), hard disk drives (HDD) or solid state drives (SDD), universal serial bus (USB) devices, serial peripheral interface (SPI) devices, and system management bus (SMBUS) devices. The PCIe devices may include expansion cards such as NICs (Network Interface Cards), redundant array of inexpensive disks (RAID) cards, field programmable gate array (FPGA) cards, solid state drive (SSD) cards, dual in-line memory devices, and graphic processing unit (GPU) cards. It is to be understood that there may be many such devices, and may include different types of devices from the devices described herein.

The south bridge chip 224 includes reliability-availability-serviceable (RAS) silicon 240 to manage error reports and other RAS functions. The south bridge chip 224 includes a set of input/output ports 242. The south bridge chip 224 also includes an SMI #port 244 that may be coupled to the BMC 214. The south bridge chip 224 also includes PCIe port 246 and a chassis open port 248. In this example, a PCIe device 250 may be coupled to the PCIe port 246 to request interrupts. It is to be understood that there may be multiple PCIe devices represented by the PCIe device 250. The chassis open port 248 may receive sensor interrupts such as a chassis open sensor 252 that requests an interrupt if the chassis of the computer system 200 is detected as open. The interrupts from the ports 244, 246, and 248 are hardware interrupts. Other input/output devices 254 such as a keyboard, mouse, or video device may access the input/output ports 242.

The platform BIOS 212 includes a PPR routine 260 that may be executed by the bootstrap processor 120 during the boot up process if the PPR routine 260 is enabled by BIOS settings. In this example, the PPR routine 260 is executed to repair DIMMs of shared volatile memory 130 that are detected as defective. The platform BIOS 212 also includes an Advanced Memory Test (AMT) routine 262. In this example, the Advanced Memory Test (AMT) is based on the Intel MRC algorithm. The AMT routine 262 enhances the memory testing sequence during BIOS boot-up to provide more reliable memory testing. The Intel AMT identifies and rectifies memory errors using the Converged-Pattern-Generator-Checker (CPGC) algorithm. The Intel AMT is enabled via a setup menu in the BIOS. Once the AMT is enabled in the BIOS setup menu, the computer requiring memory testing is rebooted. During start up, the computer enters the AMT procedure to test the full set of DIMMs of the computer.

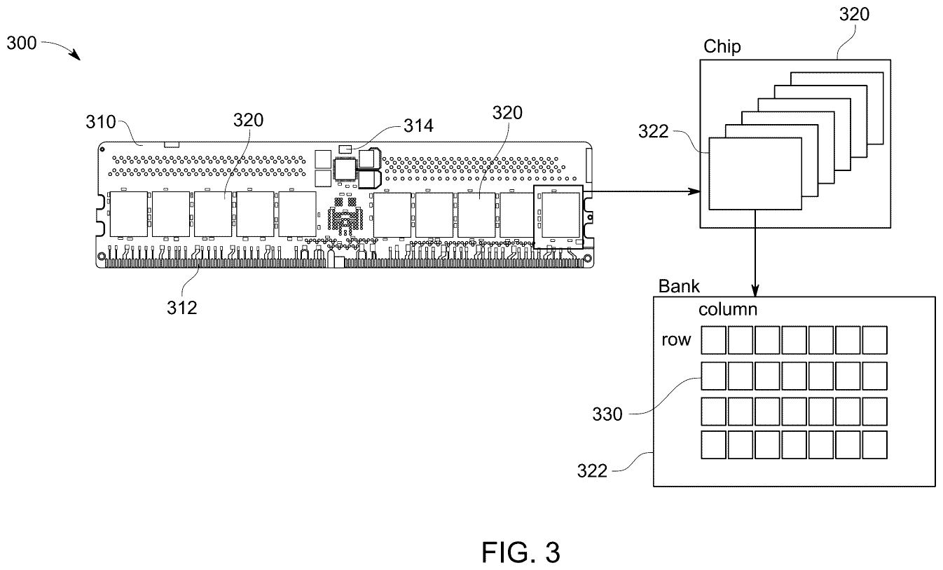

FIG. 3 shows an example dual in-line memory module (DIMM) 300 that may be one part of the shared volatile memory 230 in FIG. 2. The shared volatile memory 230 may include numerous DIMMs such as the DIMM 300. The DIMM 300 includes a circuit board 310 that includes an edge connector 312 that may be inserted in a corresponding slot on a motherboard in proximity to a processor. A permanent memory such as an Electrically Erasable Programmable Read-Only Memory (EEPROM) 314 on the circuit board 310 serves as a SPD chip for storing SPD data relating to the DIMM 300 as well as PPR related data that is written according to the example method. The circuit board 310 includes series of DRAM chips 320. Each of the DRAM chips 320 includes a series of internal memory banks 322. Each of the memory banks 322 in turn includes memory storage units 330 organized by rows and columns.

Each DIMM such as the DIMM 300 constituting the shared volatile memory 230 in FIG. 2 is tested periodically by the AMT routine 262. The AMT routine 262 will output defective rows of memory units for each bank in the DIMM 300. As will be explained, this information will be stored in the EEPROM 314 of the DIMM 300. In this manner, the error record may be stored by the DIMM and used even if the DIMM is installed in a different computer system.

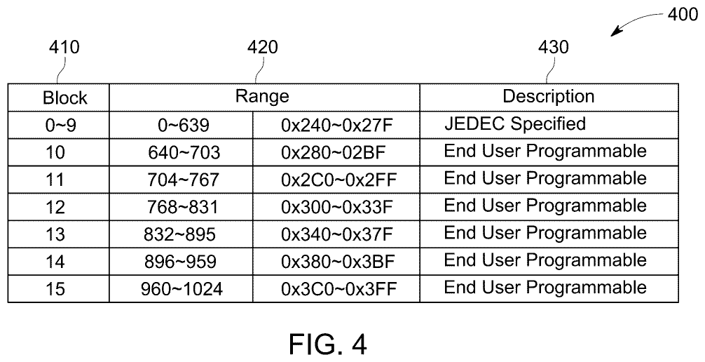

The example system and method are based on storing the sPPR count and the corresponding failed row or rows in the memory banks of a DIMM in an SPD programmable block in the EEPROM 314 of the DIMM 300. This information allows the platform BIOS 212 in FIG. 2 to perform the PPR routine 260 more efficiently based on PPR information specific to the individual DIMM and rows in the DIMM. The SPD programmable block architecture for data stored on the EEPROM 314 of the example DIMM 300 in FIG. 3 is described in the JEDEC specification JESD400-5. FIG. 4 is a table 400 of the SPD programmable block architecture. A first column 410 lists 16 blocks (0-15). A second column 420 lists the range of the blocks in both regular numerical and hex format. As shown in a third column 430, blocks 0-9 are defined by the JEDEC specification for data specific to the DIMM, but blocks 10-15 are end user programmable and used by the example method to store PPR data.

These regions in the user defined blocks 10-15 in FIG. 4 allow for storing DIMM failure information on a per-row basis for a specific DIMM. Each entry stored in the SPD block in the EEPROM records a row address, a timestamp indicating the first occurrence of an error in that row, and an sPPR count tracking the number sPPRs executed to repair the row. Every time a DIMM encounters an error that meets the PPR threshold and triggers a system reboot for sPPR, the BIOS 212 is responsible for logging the failure information into the SPD programmable blocks in the EEPROM of the particular DIMM. The example method enables the BIOS 212 to retrieve the error history of rows in the banks of a DIMM and calculate their frequency.

Based on the historical error records stored in the SPD blocks in the EEPROM of a DIMM, two example repair routines for PPR optimization may be provided for the BIOS 212. These routines include a routine to determine the type of PPR to be performed for individual rows and a routine to only selectively perform sPPR based on the past record of PPR.

To perform the optimization routines, the BIOS 212 includes the following settings: a Force sPPR threshold setting, a Force sPPR setting, a Force hPPR threshold setting, a Force hPPR setting, a Force Advanced Memory Test (AMT) setting, and an AMT threshold setting. The Force sPPR threshold setting is a value of the number of sPPRs that may be performed on the row to trigger performing a preparatory sPPR on the row. The Force sPPR setting has a value of either Enable or Disable. If the Force sPPR is enabled, the example method determines whether the system should perform preparatory sPPRs on rows that have error histories in the SPD when the recorded sPPR count for the row meet the Force sPPR Threshold setting value. In this example, the Force sPPR threshold setting is set by the user. A suitable threshold setting is 10-100 sPPRs before a preparatory sPPR is performed on a particular row.

The Force hPPR threshold setting is a value of the number of sPPRs performed before a hPPR is performed. The Force hPPR setting has a value of either Enable or Disable. If the Force hPPR setting is enabled, the method determines whether the system should perform a hPPR (as defined by the Force hPPR setting with a value of Enable or Disable) when the sPPR count for the row reaches the specified Force hPPR threshold setting value. In this example, the Force hPPR threshold setting may be selected by the user and may be in the range of 1-10 sPPRs before a hPPR is performed on the row.

The Force AMT setting threshold is a value of the number of sPPR counts that must be performed before performing an AMT on the row. The Force AMT setting has a value of Enable or Disable. If the Force AMT setting is enabled, the example routine determines whether the system should perform an AMT if the sPPR count meets the AMT Threshold value before PPR execution. In this example, the Force AMT threshold setting may be selected by the user and may be in the range of 1-10 sPPRs before an AMT is performed on the DIMM.

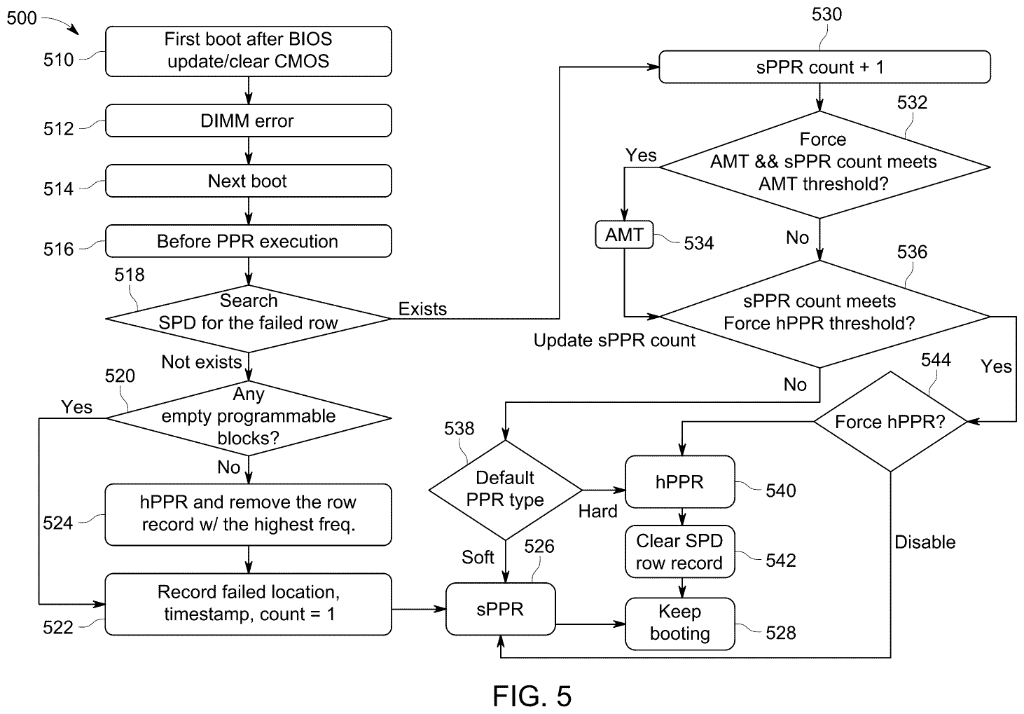

FIG. 5 is a flow diagram 500 of a first example routine using the stored sPPR count record to optimize PPR performance on a row. For a system that undergoes events such as BIOS updates, CMOS clearing, and configuration replacements, the DIMM error information stored in NVRAM 232 in FIG. 2 will be cleared, normally preventing the system from executing any PPR during the next BIOS POST. If a DIMM error occurs during runtime and the error count meets the PPR threshold, the routine will trigger a DIMM repair, typically defaulting to a sPPR in the next boot. In contrast, the example routine stores the PPR related information in the EEPROM of the DIMM, which protects the PPR related information from events such as BIOS updates, CMOS clearing, and configuration replacements that clear PPR related information stored in the NVRAM 232.

Thus, the example routine in FIG. 5 assumes a boot (510) after an event such as a BIOS update, CMOS clearing, and configuration replacement. The BIOS 212 will determine any DIMM faults during run time and store them in the NVRAM (512). For example the BIOS 212 may access an error handling processes in the reliability-availability-serviceable (RAS) routines and can record errors to registers. On the next boot (514), the BIOS 212 will enter the example routine (516) prior to accessing the PPR routine 260.

Before executing a sPPR, the BIOS 212 will attempt to retrieve the sPPR count record of all failed rows from the SPD blocks stored in the EEPROM of a DIMM (518). If the sPPR record for any failed row does not exist (518), the BIOS 212 will determine whether there are any empty programmable SPD blocks in the EEPROM (520). If there are empty blocks, the BIOS 212 will write the location of the failed row, the timestamp of the failure, and store a sPPR count with a value of one for the failed row into an empty SPD programmable block (522). If there are no available programmable blocks in SPD blocks stored in the EEPROM (520), the BIOS 212 will calculate the frequencies of error for each row and perform an hPPR for the row with the highest frequency (524). The BIOS 212 will then erase the stored record of the highest frequency row and replace the stored record with the new record of the failed row (522). The new record will include the location, a timestamp of the failure, and the sPPR count of the failed row.

The error frequency for a failed row can be calculated as:

$$Error Frequency = ( sPPR Count ) / ( Time Now - Timestamp ) .$$

After replacing the stored record with a new record of the failed row (522), the system will proceed with executing the sPPR for the failed row (526) and continue the boot (528).

If there is already a record of the failed row (518), the sPPR count for the failed row will be incremented by one (530). The routine then determines if the Force AMT setting is enabled and the sPPR count meets the set AMT threshold value (532). If the Force AMT is enabled and the sPPR count meets the AMT threshold value, the system will perform an AMT to scan for errors in the DIMM, then update the sPPR count (534).

Once any faulty DIMMs are identified by the AMT, a user can repair DIMMs where the errors are detected. After the repair, the user may rerun the AMT and check the AMT result during the BIOS POST.

After the sPPR count is updated (534), the routine determines if the sPPR count meets the Force hPPR threshold value (536). If the sPPR count does not meet the Force hPPR threshold (536), the system determines the setting for a default type of PPR (538). If the default PPR is an sPPR, the system will perform an sPPR on the faulty row (526) and will continue booting directly (528).

However, if the default PPR is a hPPR (538), a hPPR will be performed on the row (540). After the hPPR is performed, the error record of the row is erased from the SPD block (542). The routine then continues the boot process (528). If the sPPR count meets the Force hPPR threshold value (536), the routine will determine if the Force hPPR setting is enabled (544). If the Force hPPR setting is enabled (544), the system will perform a hPPR (540) on the row and clear the failed row record in the SPD block (542). The system will then continue booting (528). If the Force hPPR setting is disabled, the routine will perform an sPPR (526) instead on the row and then continue booting (528).

The example routine in FIG. 5 allows for the dynamic selection of the PPR type for different rows during the POST session without requiring setup of PPR type settings in the BIOS. The routine thus automatically performs hPPR on rows with high failure frequency to prevent unnecessary sPPRs during future boots. This reduces the need for manual system resets to switch PPR types and saves the user time in error handling. Additionally, the routine enhances system and DIMM stability by permanently replacing highly defective rows via the hPPR, rather than relying on temporary repairs through executing the sPPR during each boot.

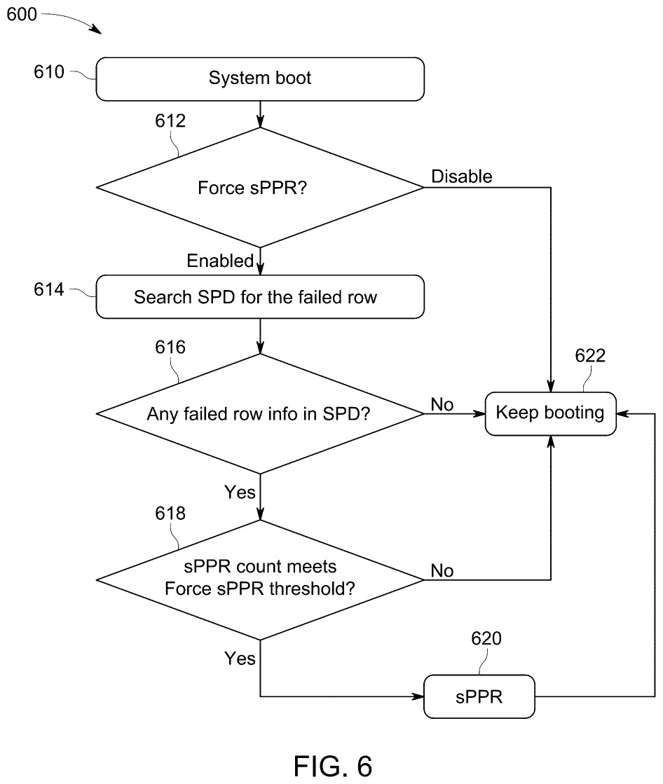

FIG. 6 shows a flow diagram 600 of an example routine to use the stored sPPR count record for a preparatory sPPR process. This procedure relies on the existing sPPR count record in the SPD block stored in the EEPROM of the DIMM to perform sPPR on DIMM rows that have previously reported errors. A system boot is initially performed (610). The routine then determines if the Force sPPR setting is enabled (612). If the Force sPPR setting is enabled, the BIOS will check the SPD programmable blocks for the sPPR count records for each row in the DIMM (614). The routine will determine if there are any recorded row failures in the sPPR count records (616). If a recorded row failure or failures are found, the routine will determine whether the sPPR count for the row meets the Force sPPR threshold value (618). If the sPPR count meets the Force sPPR threshold value, the system will proactively perform an sPPR (620) on the row where the sPPR count meets the Force sPPR threshold value to prevent potential DIMM errors.

If no failed rows are found in the sPPR count records in the SPD programmable blocks (616), the routine will continue the boot (622). If the sPPR count does not meet the Force sPPR threshold value (618), the routine will also continue the boot (622).

The flow diagrams in FIGS. 5-6 are representative of example machine readable instructions for routines to optimize utilization of PPR for DIMMs based on stored data in SPD programmable blocks in permanent memory on the DIMM. In this example, the machine readable instructions comprise an algorithm for execution by: (a) a processor; (b) a controller; and/or (c) one or more other suitable processing device(s). The algorithm may be embodied in software stored on tangible media such as flash memory, CD-ROM, floppy disk, hard drive, digital video (versatile) disk (DVD), or other memory devices. However, persons of ordinary skill in the art will readily appreciate that the entire algorithm and/or parts thereof can alternatively be executed by a device other than a processor and/or embodied in firmware or dedicated hardware in a well-known manner (e.g., it may be implemented by an application specific integrated circuit [ASIC], a programmable logic device [PLD], a field programmable logic device [FPLD], a field programmable gate array [FPGA], discrete logic, etc.). For example, any or all of the components of the interfaces can be implemented by software, hardware, and/or firmware. Also, some or all of the machine readable instructions represented by the flowcharts may be implemented manually. Further, although the example algorithm is described with reference to the flowcharts illustrated in FIGS. 5-6, persons of ordinary skill in the art will readily appreciate that many other methods of implementing the example machine readable instructions may alternatively be used. For example, the order of execution of the blocks may be changed, and/or some of the blocks described may be changed, eliminated, or combined.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A method of repairing a memory module in a computer system, the method comprising:
determining an error in a row of a memory bank of the memory module;
performing a software post package repair on the row on an initial boot of the computer system;
incrementing a number of software post package repairs performed on the row, the number of software post package repairs stored in a permanent storage device of the memory module; and
determining whether to perform another software post package repair on the row based on the stored number of software post package repairs on a subsequent boot of the computer system.

2. The method of claim 1, wherein the permanent storage device is an Electrically Erasable Programmable Read-Only Memory (EEPROM).

3. The method of claim 1, further comprising determining whether to perform a hardware post package repair for the row based on the stored number of software post package repairs.

4. The method of claim 3, further comprising:
performing the hardware post package repair on the row, wherein the determination is made based on whether the stored number of software post package repairs exceeds a threshold value; and
erasing the stored number of software post package repairs from the permanent storage device after performing the hardware post package repair on the row.

5. The method of claim 1, further comprising storing a timestamp of the error and a location of the row in the memory bank in a programmable block of the permanent storage device, wherein the stored number of software post package repairs is stored in the programmable block of the permanent storage device.

6. The method of claim 5, wherein the programmable block is a serial presence detect data region.

7. The method of claim 1, wherein the memory module is a dual in line memory module, and wherein the memory bank is one of a plurality of memory banks on the module.

8. The method of claim 1, wherein a basic input output system performs the software post package repair on the row, wherein the basic input output system includes a memory test routine, and wherein the memory test routine determines the error in the row.

9. The method of claim 8, further comprising determining whether to execute the memory test routine based on the stored number of software post package repairs.

10. The method of claim 1, wherein the row is one of a plurality of rows in the memory bank and wherein a number of software post package repairs is stored in the permanent storage device for each row of the plurality of rows with a determined error, the method further comprising:
determining there is no storage for a new number of software post package repairs for the row;
determining an error frequency for each row of the plurality of rows with a determined error, the error frequency being determined based on the stored number of software post package repairs;
performing a hardware post package repair on the row with a highest error frequency;
erasing the stored number of software post package repairs for the row with the highest error frequency from the permanent storage device; and
storing the new number of software post package repairs for the row in place of the erased stored number.

11. A computer system, comprising:
a memory module including a memory bank and a permanent storage device; and
a processor executing a basic input output system, wherein the basic input output system causes the processor to perform operations including:
determining an error in a row of a memory bank of the memory module on an initial boot of the computer system;
performing a software post package repair on the row;
incrementing a number of software post package repairs performed on the row stored in the permanent storage device; and
based on the stored number of software post package repairs, determining whether to perform a software post package repair on the row on a subsequent boot of the computer system.

12. The computer system of claim 11, wherein the permanent storage device is an Electrically Erasable Programmable Read-Only Memory (EEPROM).

13. The computer system of claim 11, wherein the operations further include determining whether to perform a hardware post package repair for the row based on the stored number of software post package repairs.

14. The computer system of claim 13, wherein the operations further include:
performing the hardware post package repair on the row, wherein the determination is made based on whether the stored number of software post package repairs exceed a threshold value; and
erasing the stored number of software post package repairs from the permanent storage device after performing the hardware post package repair on the row.

15. The computer system of claim 11, wherein the operations further include storing a timestamp of the error and a location of the row in the memory bank in a programmable block of the permanent storage device, wherein the stored number of software post package repairs is stored in the programmable block of the permanent storage device.

16. The computer system of claim 11, wherein the programmable block is a serial presence detect data region.

17. The computer system of claim 11, wherein the memory module is a dual in line memory module, and wherein the memory bank is one of a plurality of memory banks on the module.

18. The computer system of claim 11, wherein the basic input output system includes a memory test routine, and wherein the memory test routine determines the error in the row.

19. The computer system of claim 18, wherein the operations further include executing the memory test routine based on the stored number of software post package repairs.

20. A computer-program product tangibly embodied in a non-transitory machine-readable storage medium, including instructions configured to cause a data processing apparatus to perform operations including:
determining an error in a row of a memory bank of a memory module in a computer system;
performing a software post package repair on the row on an initial boot of the computer system;
incrementing a number of software post package repairs performed on the row stored in a permanent storage device of the memory module; and
determining whether to perform a software post package repair on the row based on the stored number of software post package repairs on a subsequent boot of the computer system.
